(19) United States
(12) Patent Application Publication
(10) Pub. No.: US 2017/0003500 A1
(43) Pub. Date: Jan. 5, 2017

(54) DRIVE APPARATUS

(71) Applicant: SUMITOMO PRECISION PRODUCTS CO., LTD., Hyogo (JP)

(72) Inventor: Ryohei UCHINO, Hyogo (JP)

(21) Appl. No.: 15/265,323

(22) Filed: Sep. 14, 2016

Related U.S. Application Data
(63) Continuation of application No. PCT/JP2015/001652, filed on Mar. 24, 2015.

(30) Foreign Application Priority Data
Mar. 28, 2014 (JP) 2014-068602

(51) Int. Cl. G02B 26/08; H01L 41/053

(52) U.S. Cl. CPC G02B 26/0858; H01L 41/053

(57) ABSTRACT

A mirror device 300 disclosed herein includes: a base 302; a mirror 305; an actuator 306; an extension 304 provided on the other side of the mirror 305 with respect to an X-axis opposite from the actuator 306; a fixed comb electrode 308; and a movable comb electrode 307 provided on the other side of the mirror 305 with respect to the X-axis opposite from the actuator 306. The movable comb electrode 307 includes: a beam portion 371 coupled to the mirror 305 via a hinge 373; and electrode fingers 372 provided for the beam portion 371. The extension 304 is coupled to the base 302 via a hinge 341, and the mirror 305 tilts around a principal axis passing through the hinge 341.

### TECHNICAL FIELD

The present disclosure relates to a drive apparatus.

### BACKGROUND ART

Various types of drive apparatuses have heretofore been known in the art. For example, the mirror device disclosed in Patent Document 1 includes: a base; a mirror supported by the base and functioning as a moving part; and an actuator for driving the mirror. In this mirror device, a portion of the mirror opposite from the actuator is coupled to the base via a hinge, and the mirror tilts around the hinge as the actuator is tilted.

A mirror device provided with a comb electrode to detect the magnitude of tilt of a tilting mirror is also known in the art. For example, in the mirror device disclosed in Patent Document 2, the mirror is tilted around a predetermined axis by an actuator, and the displacement of the mirror during the tilt is detected by comb electrodes. The comb electrodes include a movable comb electrode coupled to the mirror and a fixed comb electrode provided for a frame and facing the movable comb electrode. The displacement of the mirror is detected based on a variation in capacitance between these movable and fixed comb electrodes.

### CITATION LIST

### Patent Document

PATENT DOCUMENT 1: Japanese Unexamined Patent Publication No. 2013-88703

PATENT DOCUMENT 2: Japanese Unexamined Patent Publication No. 2013-160953

### SUMMARY OF INVENTION

### Technical Problem

It is possible to provide a mirror device such as the one disclosed in Patent Document 1 with a comb electrode such as the one disclosed in Patent Document 2 in order to detect the displacement of the mirror. In that case, unlike the movable comb electrode of Patent Document 2, a configuration in which the movable comb electrode is coupled to the mirror via an elastically deformable connector may be adopted. For example, if part of the displacement of the mirror is absorbed into the connector, then the movable comb electrode may be displaced only toward a desired direction.

However, in such a configuration in which the movable comb electrode is coupled to the mirror via an elastically deformable connector, the displacement of the mirror is absorbed into the connector, and therefore, it is sometimes difficult to detect the displacement of the mirror appropriately based on a variation in capacitance. For example, if the movable comb electrode is provided on the other side of the mirror opposite from the actuator and is coupled to the mirror via an elastically deformable connector, then it is difficult for the movable comb electrode to detect the displacement of the mirror accurately based on a variation in capacitance. More specifically, the mirror is coupled to the base on the opposite side from the actuator, and tilts around that coupled portion. Thus, that portion of the mirror opposite from the actuator is not displaced significantly while the mirror tilts. That is to say, if the movable comb electrode is elastically coupled to that portion of the mirror opposite from the actuator, the movable comb electrode is not displaced significantly, and the variation in capacitance decreases, even if the mirror tilts.

In view of the foregoing background, it is therefore an object of the present disclosure to accurately detect the displacement of a moving part based on a variation in capacitance in a configuration in which a movable comb electrode is coupled to the moving part via an elastically deformable connector.

### Solution to the Problem

The present disclosure provides a drive apparatus including: a base; a moving part; an actuator provided on one side of the moving part with respect to a line passing through the center of the moving part and configured to tilt the moving part; an extension provided on the other side of the moving part with respect to the line opposite from the actuator and configured to couple the moving part to the base; a fixed comb electrode provided for the base and having electrode fingers; and a movable comb electrode provided on the other side of the moving part with respect to the line opposite from the actuator and facing the fixed comb electrode. The movable comb electrode includes: a beam portion coupled to the moving part via an elastically deformable moving-part-side connector; and electrode fingers provided for the beam portion and facing the electrode fingers of the fixed comb electrode. The extension is coupled to the base via an elastically deformable extension-side connector having lower rigidity than the extension, and the moving part tilts around a principal axis passing through the base-side connector.

According to this configuration, the actuator is provided on one side, and the extension is provided on the other side, with respect to a line passing through the center of the moving part, and the extension is coupled to the base via an elastically deformable extension-side connector. As the actuator drives the moving part, the moving part tilts around a principal axis passing through the base-side connector. That is to say, one side of the moving part provided with the actuator causes a larger degree of displacement, and the other side of the moving part provided with the extension causes a smaller degree of displacement.

The movable comb electrode is provided on the opposite side from the actuator, i.e., on the same side as the extension, with respect to the line. That is to say, the movable comb electrode is provided for a portion of the moving part that causes the smaller degree of displacement. In addition, the beam portion of the movable comb electrode is coupled to the moving part via an elastically deformable moving-part-side connector. Thus, while the moving part is tilting, part of the displacement of the moving part is absorbed into the moving-part-side connector and the rest is conducted to the beam portion. In this manner, while the moving part is tilting, the displacement of the movable comb electrode tends to decrease.

In such a configuration, an extension is provided for the moving part and is coupled to the base via an elastically deformable extension-side connector. Thus, the moving part may be away from the principal axis during tilting, and the magnitude of displacement of the moving part during tilting may be increased. As a result, the magnitude of displacement of a portion of the moving part coupled to the movable comb electrode also increases. Even if part of the displacement of the moving part is absorbed into the moving-part-side connector, the magnitude of displacement of the movable comb electrode may still be increased. Consequently, the magnitude of variation in capacitance between the movable and fixed comb electrodes while the moving part is tilting may be increased so much that the displacement of the moving part may be detected accurately based on the variation in capacitance.

### Advantages of the Invention

The drive apparatus described above may detect the displacement of the moving part accurately based on a variation in capacitance.

### BRIEF DESCRIPTION OF THE DRAWINGS

FIG. 1 is a plan view of a mirror array.

FIG. 2 is a cross-sectional view of the mirror array as taken along the plane II-II shown in FIG. 2.

FIGS. 3A and 3B illustrates generally how a movable comb electrode is displaced as a mirror tilts, wherein FIG. 3A illustrates a mirror device and FIG. 3B illustrates a partial variation of the mirror device for the purpose of comparison.

FIG. 4 is a plan view of a mirror array according to another embodiment.

### DESCRIPTION OF EMBODIMENTS

Exemplary embodiments will now be described in detail with reference to the accompanying drawings.

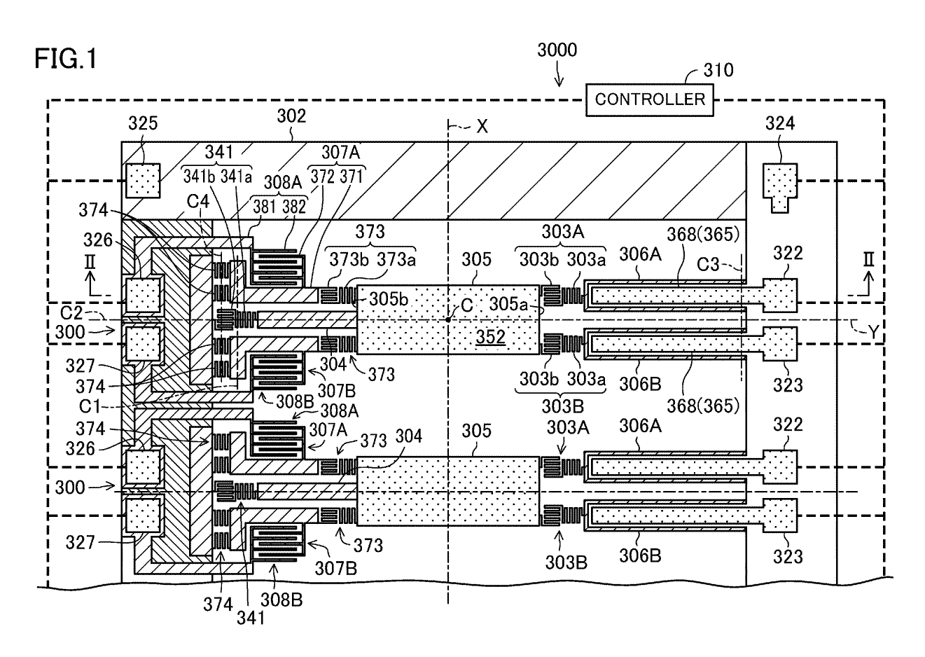

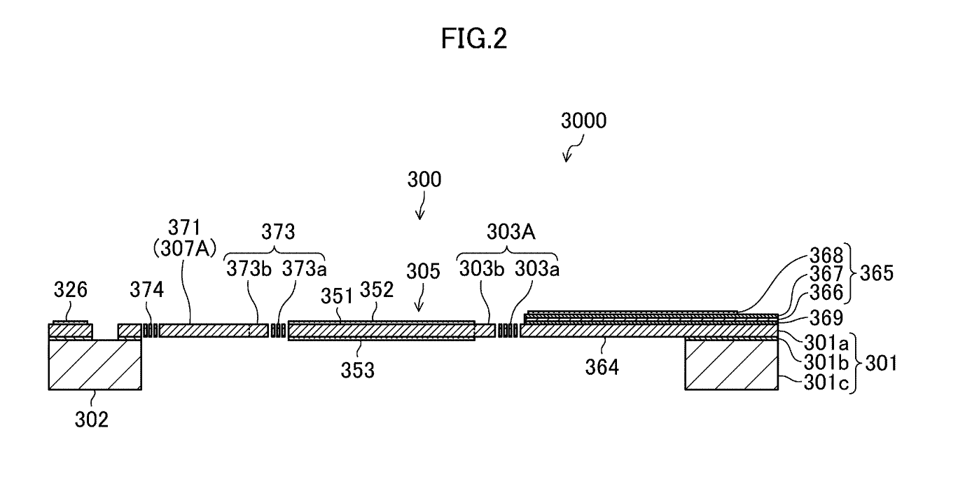

FIG. 1 is a plan view of a mirror array 3000. FIG. 2 is a cross-sectional view of the mirror array 3000 taken along the plane II-II shown in FIG. 1.

In the mirror array 3000, a plurality of mirror devices 300, 300, . . . are arranged in line. The mirror array 3000 is fabricated on a silicon on insulator (SOI) substrate 301. The SOI substrate 301 includes a first silicon layer 301a of single crystalline silicon, an oxide layer 301b of SiO₂, and a second silicon layer 301c of single crystalline silicon which are stacked one upon the other in this order.

Each of the mirror devices 300 includes: a base 302; two actuators 306, 306 coupled to the base 302; a mirror 305 coupled to the two actuators 306, 306; an extension 304 coupling the mirror 305 to the base 302; two movable comb electrodes 307, 307 coupled to the mirror 305; two fixed comb electrodes 308, 308 provided for the base 302 and facing the movable comb electrodes 307, 307; and a controller 310. Note that if these two actuators 306, 306 need to be distinguished from each other, these actuators will be hereinafter referred to as a “first actuator 306A” and a “second actuator 306B,” respectively. The mirror device 300 is an exemplary drive apparatus.

The base 302 is formed to have a substantially rectangular frame shape. The base 302 is comprised of the first silicon layer 301a, the oxide layer 301b, and the second silicon layer 301c.

The mirror 305 is formed to have a square shape in a plan view. The mirror 305 includes a mirror body 351 and a mirror-finished layer 352 stacked on the surface of the mirror body 351. The mirror body 351 is formed out of the first silicon layer 301a, while the mirror-finished layer 352 has a multilayer structure comprised of Au and Ti films. Note that another mirror-finished layer 353 similar to the mirror-finished layer 352 is also stacked on the back surface of the mirror body 351. The mirror-finished layer 353 has the function of canceling film stress caused by the mirror-finished layer 352 on the surface of the mirror body 351. As a result, the degree of planarity of the mirror body 351, and eventually, that of the mirror-finished layer 352, may be increased. The mirror 305 is an example moving part.

In this embodiment, an axis passing through the center C of every non-operating mirror 305 and extending along the surface of the base 302 (i.e., along the surface of the SOI substrate 301) and in the direction in which the mirror devices 300, 300, . . . are arranged is defined to be an X-axis. On the other hand, an axis intersecting at right angles with the X-axis at the center C of each non-operating mirror 305 and extending along the surface of the base 302 is defined to be a Y-axis. Furthermore, an axis passing through the center C of each non-operating mirror 305 and intersecting at right angles with both of the X- and Y-axes is defined to be a Z-axis. That is to say, the X-axis is common for all mirror devices 300, but the Y- and Z-axes are defined on a mirror device 300 basis.

Each of the actuators 306 includes an actuator body 364 and a piezoelectric element 365 stacked on the surface of the actuator body 364.

The actuator body 364 is formed to have a rectangular plate shape in a plan view. The actuator body 364 has one end coupled to the base 302 and extends in the Y-axis direction. The actuator body 364 is formed out of the first silicon layer 301a. As used herein, the “*-axis direction” refers to a direction that is parallel to the *-axis.

The piezoelectric element 365 is provided on the principal surface of the actuator body 364 (i.e., on the same side as the mirror-finished layer 352 of the mirrors 305). As shown in FIG. 2, an SiO₂ layer 369 is stacked on the surface of the actuator body 364, and the piezoelectric element 365 is stacked on the SiO₂ layer 369. Just like the actuator body 364, the piezoelectric element 365 is formed to have a rectangular plate shape in a plan view. The piezoelectric element 365 includes a lower electrode 366, an upper electrode 368, and a piezoelectric layer 367 sandwiched between these two electrodes 366, 368. The lower electrode 366, piezoelectric layer 367, and upper electrode 368 are stacked in this order on the SiO₂ layer 369. The piezoelectric element 365 is made of different materials from the SOI substrate 301. Specifically, the lower electrode 366 has a multilayer structure comprised of Pt and Ti films. The piezoelectric layer 367 is made of lead zirconate titanate (PZT). The upper electrode 368 has a multilayer structure comprised of Au and Ti films.

The base 302 includes: a first upper terminal 322 electrically connected to the upper electrode 368 of the first actuator 306A; a second upper terminal 323 electrically connected to the upper electrode 368 of the second actuator 306B; and a lower terminal 324 electrically connected to both of the respective lower electrodes 366 of the first and second actuators 306A and 306B. That is to say, a single first upper terminal 322 is provided for each first actuator 306A, and a single second upper terminal 323 is provided for each second actuator 306B. The lower terminal 324 is a common detection terminal provided for all lower electrodes 366.

A voltage is applied to the piezoelectric element 365 of the first actuator 306A via the first upper terminal 322 and the lower terminal 324. A voltage is applied to the piezoelectric element 365 of the second actuator 306B via the second upper terminal 323 and the lower terminal 324. Upon the application of a voltage to the piezoelectric element 365 of each actuator 306, the surface of the actuator body 364 on which the piezoelectric element 365 is stacked shrinks, thus causing the tip end of the actuator body 364 to be displaced in the Z-axis direction.

The tip end of each actuator 306 is coupled to an associated one of the mirrors 305 via an associated hinge 303. The two actuators 306, 306 are coupled to a shorter side 305a of the mirror 305 that is parallel to the X-axis. The first actuator 306A is coupled to one end of the shorter side 305a, and the second actuator 306B is coupled to the other end of the shorter side 305a.

Each of the hinges 303 is formed to be elastically deformable. Particularly, each hinge 303 includes a plurality of straight portions and a folded portion that couples together respective ends of adjacent ones of the straight portions, and has a winding shape as a whole.

The hinge 303 includes a first hinge 303a, of which the straight portions extend in the X-axis direction, and a second hinge 303b, of which the straight portions extend in the Y-axis direction. The first hinge 303a is easily flexed around an axis extending in the X-axis direction. On the other hand, the second hinge 303b is easily flexed around an axis extending in the Y-axis direction. The first hinge 303a is coupled to an associated one of the actuators 306. The second hinge 303b is coupled to an associated one of the mirrors 305.

The extension 304 is provided for the other shorter side 305b of each mirror 305 opposite from the shorter side 305a coupled to the hinges 303, 303. The extension 304 extends in the Y-axis direction from substantially the middle of the shorter side 305b. The extension 304 is fixedly coupled to the mirror 305. Specifically, the extension 304, as well as the mirror body 351, is formed out of the first silicon layer 301a.

The extension 304 is coupled to the base 302 via a hinge 341, which has lower rigidity than the extension 304 and is formed to be elastically deformable. Particularly, the hinge 341 includes a plurality of straight portions and a folded portion that couples together respective ends of adjacent ones of the straight portions, and has a winding shape as a whole. The hinge 341 includes a first hinge 341a, of which the straight portions extend in the X-axis direction, and a second hinge 341b, of which the straight portions extend in the Y-axis direction. The first hinge 341a is easily flexed around an axis extending in the X-axis direction. On the other hand, the second hinge 341b is easily flexed around an axis extending in the Y-axis direction. The first hinge 341a is coupled to the extension 304. The second hinge 341b is coupled to the base 302. The hinge 341 is an exemplary extension-side connector.

Two movable comb electrodes 307, 307 are further coupled to the shorter side 305b of each mirror 305. Each of the two movable comb electrodes 307, 307 includes a beam portion 371 extending in the Y-axis direction and three electrode fingers 372, 372, . . . provided for the beam portion 371. The beam portion 371 is provided on the same side of the mirror 305 as the extension 304 with respect to the X-axis, i.e., the opposite side of the mirror 305 from the actuators 306. The beam portion 371 extends in the Y-axis direction along the extension 304. One end of the beam portion 371 is coupled to the mirror 305 via an associated hinge 373. The beam portion 371 of one movable comb electrode 307 is coupled to one end of the shorter side 305b of the mirror 305, while the beam portion 371 of the other movable comb electrode 307 is coupled to the other end of the shorter side 305b of the mirror 305. The other end of the beam portion 371 is bent in an L shape and coupled to the base 302 via two hinges 374, 374. In this manner, the two beam portions 371, 371 and the extension 304 interposed between the two beam portions 371, 371 extend parallel to the Y-axis direction from the shorter side 305b of the mirror 305.

The three electrode fingers 372, 372, . . . are provided on the other side of the beam portion 371 opposite from the extension 304. The three electrode fingers 372, 372, . . . extend parallel to each other in the Y-axis direction and are formed in the shape of comb teeth. Note that the number of the electrode fingers 372 does not have to be three.

The hinges 373 have the same configuration as the hinges 303. That is to say, the hinges 373 are formed to be elastically deformable. Particularly, the hinges 373 each include a plurality of straight portions and a folded portion that couples together respective ends of adjacent ones of the straight portions, and have a winding shape as a whole. Each of the hinges 373 includes a first hinge 373a, of which the straight portions extend in the X-axis direction, and a second hinge 373b, of which the straight portions extend in the Y-axis direction. The first hinge 373a is easily flexed around an axis extending in the X-axis direction. On the other hand, the second hinge 373b is easily flexed around an axis extending in the Y-axis direction. The first hinge 373a is coupled to an associated one of the mirrors 305. The second hinge 373b is coupled to the beam portion 371. The hinge 373 is an exemplary mirror-side connector. The first hinge 373a is an exemplary first connector, and the second hinge 373b is an exemplary second connector.

The hinges 374 have the same configuration as the first hinges 373a. That is to say, the hinges 374 are formed to be elastically deformable. Particularly, the hinges 374 each include a plurality of straight portions extending in the X-axis direction and a folded portion that couples together respective ends of adjacent ones of the straight portions, and have a winding shape as a whole. The hinges 374 are easily flexed around an axis extending in the X-axis direction. The two hinges 374, 374 are arranged side by side in the X-axis direction. The hinge 374 is an exemplary base-side connector.

If the two movable comb electrodes 307, 307 need to be distinguished from each other, the movable comb electrode 307 coupled to one end of the shorter side 305b of their associated mirror 305 so as to face the first actuator 306A will be hereinafter referred to as a “first movable comb electrode 307A,” while the movable comb electrode 307 coupled to the other end of the shorter side 305b so as to face the second actuator 306B will be hereinafter referred to as a “second movable comb electrode 307B.”

Each of the fixed comb electrodes 308 includes a beam portion 381 extending in the Y-axis direction, and four electrode fingers 382, 382, . . . provided for the beam portion 381. The beam portion 381 extends in the Y-axis direction from an inner peripheral edge of the base 302.

The four electrode fingers 382, 382, . . . extend parallel to each other in the Y-axis direction and are formed in the shape of comb teeth. The seven electrode fingers 372, 372, . . . of an associated one of the movable comb electrodes 307 enter the gaps between the electrode fingers 382, 382, . . . . That is to say, the electrode fingers 372, 372, . . . of each movable comb electrode 307 and the electrode fingers 382, 382, . . . of an associated fixed comb electrode 308 are alternately arranged in the X-axis direction and face each other while keeping out of contact with each other. Note that the number of the electrode fingers 382 does not have to be four.

If the two fixed comb electrodes 308, 308 need to be distinguished from each other, the fixed comb electrode 308 associated with the first movable comb electrode 307A will be hereinafter referred to as a “first fixed comb electrode 308A,”, while the fixed comb electrode 308 associated with the second movable comb electrode 307B will be hereinafter referred to as a “second fixed comb electrode 308B.”

The base 302 includes detection terminals for detecting the capacitance between the movable and fixed comb electrodes 307 and 308. Particularly, the base 302 includes a movable terminal 325 electrically connected to every movable comb electrode 307, first fixed terminals 326 each electrically connected to an associated one of the first fixed comb electrodes 308A, and second fixed terminals 327 each electrically connected to an associated one of the second fixed comb electrodes 308B. That is to say, the movable terminal 325 is provided in common for all movable comb electrodes 307. A single first fixed terminal 326 is provided for each first fixed comb electrode 308A, and a single second fixed terminal 327 is provided for each second fixed comb electrode 308B.

The movable terminal 325 is provided on the surface of a portion of the first silicon layer 301a of the base 302 such that the portion is electrically conductive with all movable comb electrodes 307. Each of the first fixed terminals 326 is provided on the surface of a portion of the first silicon layer 301a of the base 302 such that the portion is electrically conductive with an associated one of the first fixed comb electrodes 308A. Each of the second fixed terminals 327 is provided on the surface of a portion of the first silicon layer 301a of the base 302 such that the portion is electrically conductive with an associated one of the second fixed comb electrodes 308B. Those portions of the first silicon layer 301a provided with the first and second fixed terminals 326 and 327 are electrically insulated from the rest of the first silicon layer 301a.

The mirror array 1 with such a configuration may be fabricated through a manufacturing process including etching the SOI substrate 301 and depositing various films on the surface thereof. For example, an SiO₂ layer 369 may be deposited on the surface of the SOI substrate 301. Next, a multilayer structure comprised of Pt and Ti films (to be the lower electrode 366), lead zirconate titanate (to be the piezoelectric layer 367), and a multilayer structure comprised of Au and Ti films (to be the upper electrode 368) are stacked in this order on the SiO₂ layer 369. Then, the structure thus obtained is subjected to photolithographic and etching processes, thereby forming a piezoelectric element 365. Subsequently, the first silicon layer 301a is subjected to an anisotropic etching process such ICP-RIE, thereby forming a mirror body 351 and an actuator body 364. Then, a multilayer structure comprised of Au and Ti films is formed on the surface of mirror body 351 to form a mirror-finished layer 352. After that, the piezoelectric element 365 is subjected to a polarization process with a predetermined voltage applied thereto.

### How This Mirror Device Operates

Next, it will be described how the mirror device 300 with such a configuration operates.

The controller 310 controls the tilt of any selected one of the mirrors 305 by applying a drive voltage to its associated mirror device 300. As the controller 310 applies a drive voltage to an associated one of the first upper terminals 322 and the lower terminal 324, the piezoelectric element 365 of the associated first actuator 306A shrinks in response to the drive voltage. The first actuator 306A has its base end coupled to the base 302, and therefore, tilts around an axis C3 that passes through the base end and that is parallel to the X-axis. In addition, as the controller 310 applies a drive voltage to an associated one of the second upper terminals 323 and the lower terminal 324, the piezoelectric element 365 of the associated second actuator 306B shrinks in response to the drive voltage. Just like the first actuator 306A, the second actuator 306B also has its base end coupled to the base 302, and therefore, tilts around the axis C3 that passes through the base end and that is parallel to the X-axis. The controller 310 outputs the drive voltages to the first and second actuators 306A and 306B independently of each other. That is to say, the controller 310 controls the magnitudes of tilt of the first and second actuators 306A and 306B independently of each other.

As the first actuator 306A tilts, the tip end of the first actuator 306A is displaced accordingly, and a portion of the associated mirror 305 coupled to the associated hinge 303A is displaced in response. Likewise, as the second actuator 306B tilts, the tip end of the second actuator 306B is displaced accordingly, and a portion of the associated mirror 305 coupled to the associated hinge 303B is displaced in response. Since the magnitude of tilt of each actuator 306 is very small, the displacement of the tip end of the actuator 306 may be regarded as a displacement in the Z-axis direction.

The mirror 305 is coupled to the base 302 via the associated extension 304 and hinge 341, and therefore, tilts overall on the hinge 341 as a supporting point. Particularly, the mirror 305 tilts not only around a principal axis C1 that passes through the hinge 341 and that is parallel to the X-axis but also around a second axis C2 that passes through the hinge 341 and the center C of the mirror 305 as well. While the mirror 305 is not operating, the second axis C2 agrees with the Y-axis.

For example, if the magnitude of tilt of the first actuator 306A is the same as that of the second actuator 306B, then the magnitude of displacement in the Z-axis direction of a portion of the shorter side 305a of the mirror 305 coupled to the hinge 303A is the same as that of another portion of the shorter side 305a of the mirror 305 coupled to the hinge 303B. As a result, the mirror 305 tilts around the principal axis C1.

On the other hand, if the magnitude of tilt of the first actuator 306A is different from that of the second actuator 306B, then the magnitude of displacement in the Z-axis direction of a portion of the shorter side 305a of the mirror 305 coupled to the hinge 303A is different from that of another portion of the shorter side 305a of the mirror 305 coupled to the hinge 303B. As a result, the mirror 305 tilts around the second axis C2.

In this manner, the controller 310 adjusts the respective magnitudes of tilt of the first and second actuators 306A and 306B, thereby tilting the mirror 305 in an arbitrary direction by combining the respective tilts of the mirror 305 around the principal and second axes C1 and C2.

While tilting the mirror 305, the controller 310 detects the magnitude of tilt of the mirror 305 based on the capacitance between the movable and fixed comb electrodes 307 and 308.

Particularly, as the mirror 305 tilts with the actuators 306 activated, the movable comb electrodes 307 also tilt accordingly. In this case, one end of the beam portion 371 of each movable comb electrode 307 is coupled to an associated mirror 305 via an associated hinge 373, while the other end of the beam portion 371 is coupled to the base 302 via two associated hinges 374, 374. Thus, as the mirror 305 tilts, a portion of the beam portion 371 coupled to the hinge 373 is displaced along with the displacement of the mirror 305, and tilts as a whole around the tilt axis C4 on the two hinges 374, 374 as supporting points. As a result, respective portions of the electrode fingers 372, 372, . . . of each movable comb electrode 307 and the electrode fingers 382, 382, . . . of an associated fixed comb electrode 308 that face each other change their area, thus causing a variation in the capacitance between the movable and fixed comb electrodes 307 and 308.

Since the first movable comb electrode 307A is coupled to one end of the shorter side 305b of the associated mirror 305 via the associated hinge 373, the displacement in the Z-axis direction of the one end of the shorter side 305b may be detected based on the capacitance between the first movable comb electrode 307A and the first fixed comb electrode 308A. On the other hand, since the second movable comb electrode 307B is coupled to the other end of the shorter side 305b via the associated hinge 373, the displacement in the Z-axis direction of the other end of the shorter side 305b may be detected based on the capacitance between the second movable comb electrode 307B and the second fixed comb electrode 308B.

The controller 310 detects the capacitance between the first movable comb electrode 307A and the first fixed comb electrode 308A via the movable terminal 325 and an associated one of the first fixed terminals 326. The controller 310 also detects the capacitance between the second movable comb electrode 307B and the second fixed comb electrode 308B via the movable terminal 325 and an associated one of the second fixed terminals 327. The controller 310 regulates the respective voltages applied to the first and second actuators 306A and 306B based on the capacitance between the first movable comb electrode 307A and the first fixed comb electrode 308A and the capacitance between the second movable comb electrode 307B and the second fixed comb electrode 308B, respectively, thereby controlling the magnitude of tilt of the mirror 305.

In this case, each mirror 305 tilts around two axes, and therefore, both ends of the shorter side 305b of the mirror 305 tilt not only around the principal axis C1 but also around the second axis C2 as well. On the other hand, in each of the movable comb electrodes 307, one end of the beam portion 371 is coupled to an end of the shorter side 305b of the associated mirror 305 via an elastically deformable hinge 373. Thus, part of the displacement of the mirror 305 is absorbed into the hinge 373 and the rest of the displacement is conducted to the movable comb electrode 307. That is why among the displacements of the ends of the shorter side 305b, the more dominant displacement in the Z-axis direction is mostly conducted to the movable comb electrodes 307, and the displacement around the second axis C2 is hardly conducted to the movable comb electrodes 307. As a result, the tilt of the movable comb electrodes 307 around the Y-axis is minimized and the movable comb electrodes 307 tilt such that a portion of their beam portion 371 coupled to the hinge 373 is displaced substantially only in the Z-axis direction.

Thus, the capacitance between the movable and fixed comb electrodes 307 and 308 may be detected accurately. More specifically, the electrode fingers 372, 372, . . . of each movable comb electrode 307 and the electrode fingers 382, 382, . . . of an associated fixed comb electrode 308 are alternately arranged in the X-axis direction and face each other while keeping out of contact with each other. In this state, as the movable comb electrode 307 tilts around the tilt axis C4, i.e., is displaced within the YZ plane, respective portions of the electrode fingers 372, 372, . . . and the electrode fingers 382, 382, . . . that face each other change their area to cause a variation in capacitance between the movable and fixed comb electrodes 307 and 308. However, if the movable comb electrode 307 were displaced toward the direction of the tilt axis C4 or tilted around an axis parallel to the Y-axis, the gap between the electrode fingers 372, 372, . . . and the electrode fingers 382, 382, . . . would change so much as to cause a variation in capacitance for a reason other than the tilt of the movable comb electrode 307 around the tilt axis C4. Furthermore, if the electrode fingers 372, 372, . . . contacted with the electrode fingers 382, 382, . . . , then the capacitance could not be detected anymore. In contrast, if the movable comb electrode 307 is tilted so as to be displaced substantially only in the Z-axis direction, the area of the portions of the electrode fingers 372, 372, . . . and the electrode fingers 382, 382, . . . that face each other may be changed with the size of their gap maintained. As a result, the variation in capacitance caused between the movable and fixed comb electrodes 307 and 308 due to the tilt of the movable comb electrode 307 around the tilt axis C4 may be detected accurately.

Also, the other end of the beam portion 371 of each movable comb electrode 307 is coupled to the base 302 at least at two points arranged along the tilt axis C4. Particularly, the beam portion 371 is coupled to the base 302 via the two hinges 374, 374 which are arranged side by side along the tilt axis C4. Thus, the beam portion 371 tends to tilt more easily around the tilt axis C4 and to tilt less easily around an axis other than the tilt axis C4.

Furthermore, since the straight portions of each hinge 374 extend in the X-axis direction (i.e., along the tilt axis C4), the hinge 374 has such a shape that causes the hinge 374 to be flexed more easily around an axis parallel to the tilt axis C4 than around an axis perpendicular to the tilt axis C4. For this reason as well, the beam portion 371 tends to tilt more easily around the tilt axis C4 and to tilt less easily around an axis other than the tilt axis C4.

In addition, each hinge 373 coupling an associated beam portion 371 to an associated mirror 305 is configured to tilt easily around an axis parallel to the Y-axis as well. Thus, in conducting the displacement of the mirror 305 to the beam portion 371, the hinge 373 may absorb the tilt around the axis parallel to the Y-axis. As a result, even if the mirror 305 tilts around the second axis C2, the movable comb electrode 307 is allowed to tilt substantially only around the tilt axis C4.

Thus, the movable comb electrode 307 may be tilted substantially only around the tilt axis C4, and a variation in capacitance caused between the movable and fixed comb electrodes 307 and 308 due to the tilt of the movable comb electrode 307 around the tilt axis C4 may be detected accurately as well.

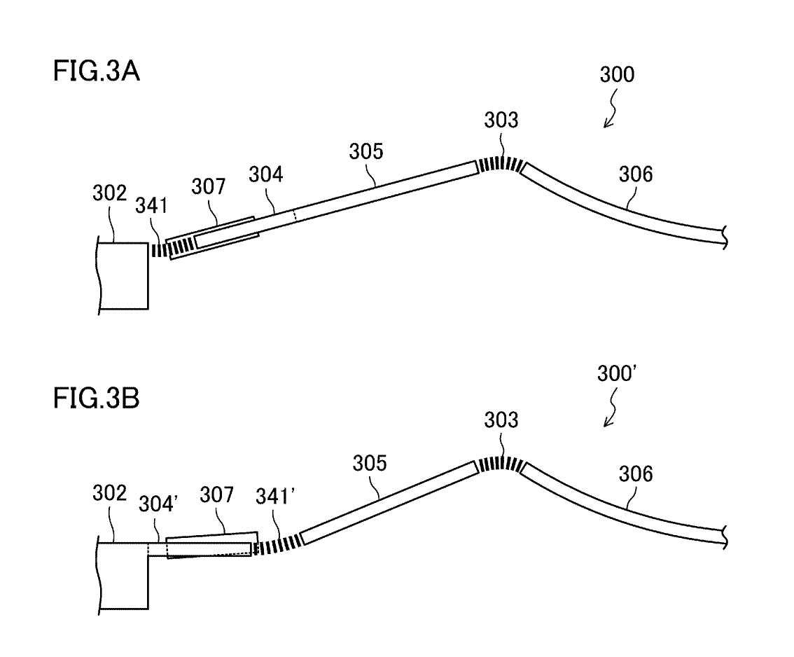

In such a configuration in which each movable comb electrode 307 is coupled to an associated mirror 305 via an associated hinge 373, if the displacement of the mirror 305 were absorbed too much into the hinge 373, it would be difficult to detect appropriately the displacement of the mirror 305 based on a variation in capacitance. To cope with this problem, an extension 304 is provided to extend from the mirror 305 toward the base 302 such that one end of the extension 304 closer to the base 302 is coupled to the base 302 via a hinge 341. Thus, the tilt of the mirror 305 may be detected accurately based on a variation in capacitance between the movable and fixed comb electrodes 307 and 308. This point will be described with reference to FIGS. 3A and 3B. FIGS. 3A and 3B illustrates generally how the movable comb electrode 307 is displaced as the mirror 305 tilts, wherein FIG. 3A illustrates a mirror device 300 and FIG. 3B illustrates a partial variation of the mirror device 300 for the purpose of comparison.

In the mirror device 300′ shown in FIG. 3B, an extension 304′ is coupled fixedly to the base 302, and one end of the extension 304′ closer to a mirror 305 is coupled to the mirror 305 via a hinge 341′. In such a configuration, the mirror 305 tilts around a tilt axis near the hinge 341′. That is why even if the mirror 305 tilts, the extension 304′ is not displaced but remains parallel to the surface of the base 302, and therefore, the shorter side 305b is displaced only slightly in the Z-axis direction. As a result, the movable comb electrode 307 tilts only slightly as well. Consequently, even if the mirror 305 tilts, the capacitance between the movable and fixed comb electrodes 307 and 308 does not vary significantly, and it is difficult to detect appropriately the tilt of the mirror 305 based on a variation in capacitance.

In contrast, as shown in FIG. 3A, the extension 304 is coupled fixedly to an associated mirror 305, and one end of the extension 304 closer to the base 302 is coupled to the base 302 via an associated hinge 341. In this configuration, the mirror 305 tilts around a principal axis C1 that passes through the hinge 341. Since the shorter side 305b is more distant from the tilt axis of the mirror 305 than in the situation shown in FIG. 3B, the shorter side 305b is displaced more significantly in the Z-axis direction than in the configuration shown in FIG. 3B as the mirror 305 tilts. As a result, as the mirror 305 tilts, the movable comb electrode 307 tilts more significantly. Consequently, as the mirror 305 tilts, the capacitance between the movable and fixed comb electrodes 307 and 308 varies so significantly that the tilt of the mirror 305 may be detected accurately based on the variation in capacitance.

As can be seen, the displacement of the movable comb electrode 307 around the tilt axis C4 may be increased with the displacements of the movable comb electrode 307 around other axes reduced. As a result, the magnitude of variation in capacitance between the movable and fixed comb electrodes 307 and 308 may be increased with the movable comb electrode 307 kept out of contact with the fixed comb electrode 308, and therefore, the tilt of the mirror 305 may be detected accurately.

Furthermore, in a configuration such as this mirror array 3000 in which a plurality of mirror devices 300, 300, . . . are arranged in a predetermined arrangement direction (i.e., in the X-axis direction in this example), the size of each of those mirror devices 300 as measured in the arrangement direction needs to be reduced. In that case, it is recommended that the actuators 306 and movable comb electrodes 307 coupled to each mirror 305 be arranged with respect to the mirror 305 in a direction perpendicular to the arrangement direction (i.e., in the Y-axis direction in this example). In the mirror device 300, the actuators 306 are arranged on one side of the mirror 305 in the direction perpendicular to the arrangement direction, while the movable comb electrodes 307 are arranged on the other side of the mirror 305 in that direction. As a result, the size of the mirror device 300 as measured in the arrangement direction may be reduced, and the space of the mirror 305 in the direction perpendicular to the arrangement direction may be used effectively.

Furthermore, in such a configuration, if the extension 304 is extended from the mirror 305 to the same side as the movable comb electrodes 307 and coupled to the base 302 via the hinge 341, the tilt of the mirror 305 may be detected highly accurately with the movable comb electrodes 307 kept out of contact with the fixed comb electrodes 308 as described above.

As can be seen from the foregoing description, the mirror device 300 includes: a base 302; a mirror 305; an actuator 306 provided on one side of the mirror 305 with respect to a line (i.e., X-axis) passing through the center of the mirror 305 and configured to tilt the mirror 305; an extension 304 provided on the other side of the mirror 305 with respect to the X-axis opposite from the actuator 306 and configured to couple the mirror 305 to the base 302; a fixed comb electrode 308 provided for the base 302 and having electrode fingers 382, 382, . . . ; and a movable comb electrode 307 provided on the other side of the mirror 305 with respect to the X-axis opposite from the actuator 306 and facing the fixed comb electrode 308. The movable comb electrode 307 includes: a beam portion 371 coupled to the mirror 305 via an elastically deformable hinge 373; and electrode fingers 372, 372, . . . provided for the beam portion 371 and facing the electrode fingers 382, 382, . . . of the fixed comb electrode 308. The extension 304 is coupled to the base 302 via an elastically deformable hinge 341 having lower rigidity than the extension 304, and the mirror 305 tilts around a principal axis C1 passing through the hinge 341.

According to this configuration, the actuator 306 is provided on one side, and the extension 304 is provided on the other side, with respect to the X-axis passing through the center C of the mirror 305, and the extension 304 is coupled to the base 302 via an elastically deformable hinge 341. As the actuator 306 drives the mirror 305, the mirror 305 tilts around a principal axis C1 passing through the hinge 341. In this embodiment, the movable comb electrode 307 is provided on the opposite side from the actuator 306, i.e., on the same side as the extension 304, with respect to the X-axis. The beam portion 371 of the movable comb electrode 307 is coupled to the mirror 305 via an elastically deformable hinge 373. Thus, while the mirror 305 is tilting, part of the displacement of the mirror 305 is absorbed into the hinge 373 and the rest is conducted to the beam portion 371.

In such a configuration, an extension 304 is provided for the mirror 305 and is coupled to the base 302 via an elastically deformable hinge 341. As a result, the mirror 305 may be away from the principal axis C1, and the magnitude of displacement of the mirror 305 during tilting may be increased. Thus, even if part of the displacement of the mirror 305 is absorbed into the hinge 373, the magnitude of displacement of the movable comb electrode 307 may be increased. As a result, the magnitude of variation in capacitance between the movable and fixed comb electrodes 307, 308 while the mirror 305 is tilting may be increased so much that the displacement of the mirror 305 may be detected accurately based on the variation in capacitance.

In one embodiment, the extension 304 extends from the mirror 305 toward the beam portion 371.

According to this configuration, the extension 304 and the movable comb electrode may be arranged in a narrower space on one side of the mirror 305 in the Y-axis direction.

In another embodiment, the beam portion 371 is coupled to the base 302 so as to tilt more easily around an axis parallel to the principal axis C1 than around an axis perpendicular to the principal axis C1.

According to this configuration, not only the tilt of the mirror 305 around the Y-axis may be absorbed into the hinge 373, but also the structure of supporting the beam portion 371 to the base 302 tends to tilt less easily around axes other than the axis parallel to the principal axis C1. As a result, the tilt of the movable comb electrode 307 around the Y-axis may be reduced so much that the movable comb electrode 307 is displaced substantially only in the Z-axis direction. Consequently, the variation in capacitance between the movable and fixed comb electrodes 307 and 308 due to the tilt of the movable comb electrode 307 around an axis parallel to the X-axis may be detected accurately.

In a specific embodiment, the beam portion 371 is coupled to the base 302 via an elastically deformable hinge 374 and the hinge 374 is configured to be flexed more easily around the axis parallel to the principal axis C1 than around the axis perpendicular to the principal axis C1. More specifically, the hinge 374 includes a plurality of straight portions extending in the X-axis direction and a folded portion connecting ends of adjacent ones of the straight portions, and has a winding shape as a whole.

Thus, the tilt of the beam portion 371 around the Y-axis may be reduced.

In yet another embodiment, the beam portion 371 is coupled to the base 302 via a plurality of elastically deformable hinges 374, 374, and the plurality of hinges 374, 374 are arranged side by side along the principal axis.

In this manner, if the beam portion 371 is coupled to the base 302 via a plurality of hinges 374, 374 arranged along the principal axis, the tilt of the beam portion 371 around the Y-axis may be reduced.

In yet another embodiment, the hinge 373 includes a first hinge 373a which is flexed more easily around the axis parallel to the principal axis than around the axis perpendicular to the principal axis, and a second hinge 373b which is flexed more easily around the axis perpendicular to the principal axis than around the axis parallel to the principal axis.

According to this configuration, the hinge 373 includes at least a second hinge 373b, and therefore, may absorb the tilt of the mirror 305 around the Y-axis and reduce the tilt to be conducted to the movable comb electrode 307.

### OTHER EMBODIMENTS

Embodiments have just been described as examples of the technique disclosed in the present application. However, the present disclosure is not limited to those exemplary embodiments, but is also applicable to other embodiments which are altered or substituted, to which other features are added, or from which some features are omitted, as needed. Optionally, the components described in those embodiments may be combined to create a new embodiment. The components illustrated on the accompanying drawings and described in the detailed description include not only essential components that need to be used to overcome the problem, but also other unessential components that do not have to be used to overcome the problem but that are illustrated or mentioned there just for the sake of showing a typical example of the technique. Therefore, such unessential components should not be taken for essential ones, simply because such unessential components are illustrated in the drawings or mentioned in the detailed description.

The embodiments described above may be modified in the following manner.

The embodiments described above are directed to a mirror array. However, the configuration described above is also applicable to an embodiment that uses only one mirror device.

Also, the shapes, sizes, and materials adopted in the embodiments described above are only examples and in no way limiting, either. For example, the mirror 305 does not have to have a square shape in a plan view, but may also have a circular or any other polygonal shape.

The respective hinges do not have to have the configuration described for those embodiments, either. For example, as long as each hinge has lower rigidity than a member coupled thereto and is elastically deformable, the hinge may have any arbitrary configuration. The hinge 341 may include only one of the first and second hinges 341a and 341b. Likewise, the hinge 373 may include only one of the first and second hinges 373a and 373b. The number of the hinges 374 to provide does not have to be two but may also be one or three or more. Furthermore, just like the hinges 341 and 373, the hinges 374 may also include a hinge that tends to be flexed easily around an axis extending in the X-axis direction and a hinge that tends to be flexed easily around an axis extending in the Y-axis direction.

The actuators 306 do not have to have the configurations described above, either. Also, the actuators 306 each have a piezoelectric element 365, but it is only an exemplary embodiment. For example, those actuators may also be each implemented as an actuator driving a mirror with electrostatic attraction. Furthermore, the piezoelectric elements 365 may use, in their piezoelectric layer, KNN ((K, Na)NbO₃) that is a non-lead piezoelectric material instead of PZT. Moreover, each mirror device 300 may include only one actuator as well.

Furthermore, the actuators 306 may be coupled to any portion of their associated mirror 305 other than the shorter side 305a thereof. Likewise, the extension 304 and movable comb electrodes 307 may also be coupled to any portion of their associated mirror 305 other than the shorter side 305b thereof. That is to say, the actuators 306 may be provided on one side of the associated mirror 305 with respect to the line passing through the center C of the mirror 305, and the extension 304 and the movable comb electrodes 307 may be provided on the other side of the mirror 305. Also, in the embodiments described above, the actuators 306, the extensions 304, and the movable comb electrodes 307 are not arranged in the X-axis direction along the mirrors 305. However, some of the actuators 306, extensions 304, and movable comb electrodes 307 may be arranged in the space between the mirrors 305 in the X-axis direction.

The configurations of the movable comb electrodes 307 and fixed comb electrodes 308 described above are just exemplary ones, and any other configurations may be adopted for them as well. For example, the movable comb electrodes 307 may be provided for the beam portion extending in the Y-axis direction from a longer side of each mirror 305. The locations of the movable comb electrodes 307 and the directions in which their electrode fingers extend may be defined arbitrarily. For example, the electrode fingers 372, 372, . . . of the movable comb electrodes 307 and the electrode fingers 382, 382, . . . of the fixed comb electrodes 308 do not have to extend in the Y-axis direction but may extend in the X-axis direction, for example.

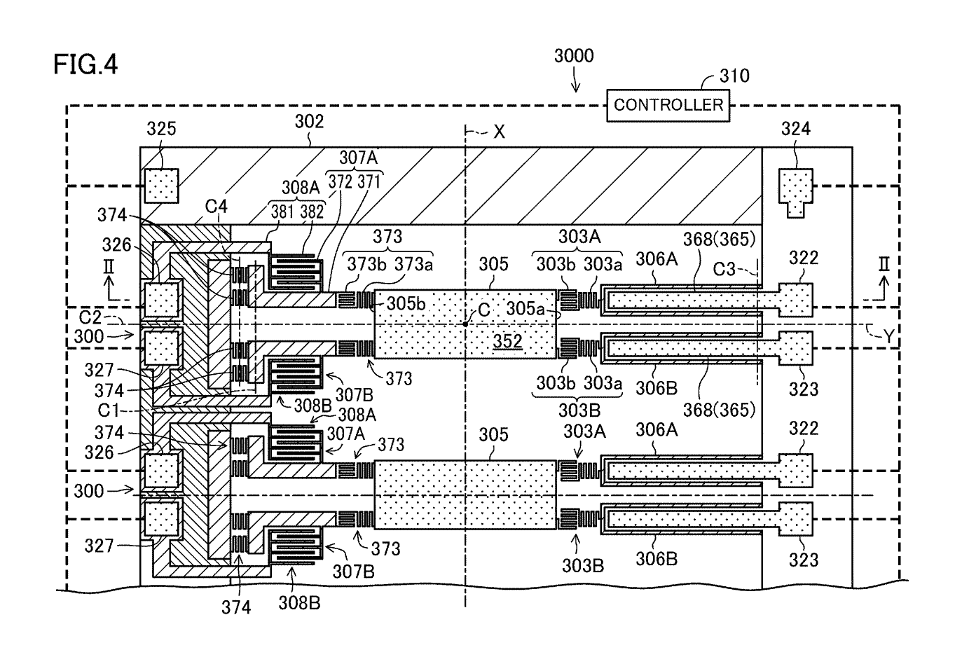

Furthermore, in each of the mirror devices 300, the mirror 305 is coupled to the base 302 via the extension 304. However, this is only an exemplary embodiment. For example, as shown in FIG. 4, the extension 304 and the hinge 341 may be omitted. In that case, the mirror 305 is coupled to the base 302 via the movable comb electrodes 307. If the mirror 305 is coupled to the base 302 via the movable comb electrodes 307 with the extension 304 and hinge 341 omitted, the size of the mirror device 300 as measured in the arrangement direction thereof may be reduced.

The mirror device 300 is an exemplary drive apparatus. However, the drive apparatus does not have to be a one that drives a mirror. For example, the drive apparatus may also be a shutter device configured to drive a blade or plate as a moving part with an actuator.

Note that the embodiments described above are just typical examples in nature and are not intended to limit the scope, application or uses of the present disclosure.

### INDUSTRIAL APPLICABILITY

As can be seen from the foregoing description, the present disclosure is useful for a drive apparatus.

### DESCRIPTION OF REFERENCE CHARACTERS

3000 Mirror Array

300 Mirror Device (Drive Apparatus)

302 Base

304 Extension

341 Hinge (Extension-Side Connector)

305 Mirror (Moving Part)

306 Actuator

307 Movable Comb Electrode

371 Beam Portion

372 Electrode Finger

373 Hinge (Moving-Part-Side Connector)

373a First Hinge (First Connector)

373b Second Hinge (Second Connector)

374 Hinge (Base-Side Connector)

308 Fixed Comb Electrode

382 Electrode Finger

1. A drive apparatus comprising:
a base;
a moving part;
an actuator provided on one side of the moving part with respect to a line passing through the center of the moving part and configured to tilt the moving part;
an extension provided on the other side of the moving part with respect to the line opposite from the actuator and configured to couple the moving part to the base;
a fixed comb electrode provided for the base and having electrode fingers; and
a movable comb electrode provided on the other side of the moving part with respect to the line opposite from the actuator and facing the fixed comb electrode, wherein
the movable comb electrode includes: a beam portion coupled to the moving part via an elastically deformable moving-part-side connector; and electrode fingers provided for the beam portion and facing the electrode fingers of the fixed comb electrode,
the extension is coupled to the base via an elastically deformable extension-side connector having lower rigidity than the extension, and
the moving part tilts around a principal axis passing through the extension-side connector.

2. The drive apparatus of claim 1, wherein
the extension extends from the moving part toward the beam portion.

3. The drive apparatus of claim 1, wherein
the beam portion is coupled to the base so as to tilt more easily around an axis parallel to the principal axis than around an axis perpendicular to the principal axis.

4. The drive apparatus of claim 3, wherein
the beam portion is coupled to the base via an elastically deformable base-side connector, and
the base-side connector is configured to be flexed more easily around the axis parallel to the principal axis than around the axis perpendicular to the principal axis.

5. The drive apparatus of claim 3, wherein
the beam portion is coupled to the base via a plurality of elastically deformable base-side connectors, and
the plurality of base-side connectors are arranged side by side along the principal axis.

6. The drive apparatus of claim 1, wherein
the moving-part-side connector includes a first connector which is flexed more easily around the axis parallel to the principal axis than around the axis perpendicular to the principal axis, and a second connector which is flexed more easily around the axis perpendicular to the principal axis than around the axis parallel to the principal axis.

7. The drive apparatus of claim 2, wherein
the moving-part-side connector includes a first connector which is flexed more easily around the axis parallel to the principal axis than around the axis perpendicular to the principal axis, and a second connector which is flexed more easily around the axis perpendicular to the principal axis than around the axis parallel to the principal axis.

8. The drive apparatus of claim 3, wherein
the moving-part-side connector includes a first connector which is flexed more easily around the axis parallel to the principal axis than around the axis perpendicular to the principal axis, and a second connector which is flexed more easily around the axis perpendicular to the principal axis than around the axis parallel to the principal axis.

9. The drive apparatus of claim 4, wherein
the moving-part-side connector includes a first connector which is flexed more easily around the axis parallel to the principal axis than around the axis perpendicular to the principal axis, and a second connector which is flexed more easily around the axis perpendicular to the principal axis than around the axis parallel to the principal axis.

10. The drive apparatus of claim 5, wherein
the moving-part-side connector includes a first connector which is flexed more easily around the axis parallel to the principal axis than around the axis perpendicular to the principal axis, and a second connector which is flexed more easily around the axis perpendicular to the principal axis than around the axis parallel to the principal axis.
